(19) United States
(12) Patent Application Publication
(10) Pub. No.: US 2009/0087592 A1
(43) Pub. Date: Apr. 2, 2009

(54) COLOR FILTER FOR LIQUID CRYSTAL DISPLAY DEVICE

(75) Inventors: Pei-Yu Chen, Hsinchu (TW); Hsueh-Ying Huang, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORP., Hsinchu (TW)

(21) Appl. No.: 11/945,336

(22) Filed: Nov. 27, 2007

(30) Foreign Application Priority Data
Oct. 2, 2007 (TW) 96136862

(51) Int. Cl. B32B 25/04; G03F 3/00

(52) U.S. Cl. 428/1.31; 430/7

(57) ABSTRACT

A color filter (CF) is provided. The CF includes a plurality of series of red resist pattern layers, a plurality of series of green resist pattern layers, and a plurality of series of blue resist pattern layers alternately arranged in an array. Each of the plurality of series of red resist pattern layers and each of the plurality of series of green resist pattern layers include a colorant consisting of pigment, respectively, and at least one series of blue resist pattern layers include a colorant consisting of dye or a mixture of dye and pigment. A liquid crystal display (LCD) device utilizing the CF is also disclosed.

### BACKGROUND OF THE INVENTION

1. Field of the Invention

The invention relates to a color filter (CF) and in particular to a color filter and a liquid crystal display (LCD) device having the same, capable of improving contrast ratio.

2. Description of the Related Art

Due to thin profile, light weight, low power consumption, and low operating voltage characteristics of LCDs, LCDs are widely employed in electronic products, such as portable personal computers, digital cameras, projectors, and the like.

A typical LCD includes an array substrate, a color filter (CF) substrate, and a liquid crystal layer disposed therebetween. The array substrate contains a plurality of matrix pixels consisting of a plurality of data lines and a plurality of scan lines, and a plurality of pixel driving circuits consisting of a plurality of electric devices, such as thin film transistors (TFTs) and storage capacitors. The CF substrate is constituted of red, green, and blue color pattern layers corresponding to the matrix pixels and light-intercepting black matrixes in the peripheries of the color pattern layers to increase the display contrast. The liquid crystal layer works as a movable shutter by switching electrodes corresponding to each of the red, green, and blue pixels on and off, such that light passes through each of the red, green, and blue color pattern layers or not.

Such color pattern layers typically comprises a colorant which selectively transmits red, green, or blue light. Generally, pigments are widely used as the colorant due to better durability of pigments. However, the particle size of pigments is more than 1 μm, thus high light scattering results, aggravating dark-state light leakage of device and reducing image contrast of device.

Therefore, there exists a need for an improved CF substrate capable of increasing image contrast of the pixels.

### BRIEF SUMMARY OF INVENTION

A detailed description is given in the following embodiments with reference to the accompanying drawings. A color filter (CF) and a liquid crystal display (LCD) device are provided. An embodiment of a CF comprises a plurality of series of red resist pattern layers, a plurality of series of green resist pattern layers, and a plurality of series of blue resist pattern layers alternately arranged in an array. Each of the plurality of series of red resist pattern layers and each of the plurality of series of green resist pattern layers comprise a colorant consisting of pigment, respectively, and at least one series of blue resist pattern layers comprise a colorant consisting of dye or a mixture of dye and pigment.

Another embodiment of a CF comprises a plurality of series of red resist pattern layers, a plurality of series of green resist pattern layers, and a plurality of series of blue resist pattern layers alternately arranged in an array. The plurality of odd series of red, green, and blue resist pattern layers in the array comprise colorants consisting of pigment and the plurality of even series of red, green, and blue resist pattern layers in the array comprises colorants consisting of dye.

An embodiment of an LCD device comprises a lower substrate, an upper substrate opposite to lower substrate, a liquid crystal layer disposed between the lower and upper substrates and a CF disposed between the liquid crystal layer and the upper substrate. The CF comprises a plurality of series of red resist pattern layers, a plurality of series of green resist pattern layers, and a plurality of series of blue resist pattern layers alternately arranged in an array. Each of the plurality of series of red resist pattern layers and each of the plurality of series of green resist pattern layers comprise a colorant consisting of pigment, respectively, and at least one series of blue resist pattern layers comprise a colorant consisting of dye or a mixture of dye and pigment.

Another embodiment of an LCD device comprises a lower substrate, an upper substrate opposite to the lower substrate, a liquid crystal layer disposed between the lower and upper substrates and a CF disposed between the liquid crystal layer and the upper substrate. The CF comprises a plurality of series of red resist pattern layers, a plurality of series of green resist pattern layers, and a plurality of series of blue resist pattern layers alternately arranged in an array. The plurality of odd series of red, green, and blue resist pattern layers in the array comprise colorants consisting of pigment and the plurality of even series of red, green, and blue resist pattern layers in the array comprises colorants consisting of dye.

### BRIEF DESCRIPTION OF DRAWINGS

The invention can be more fully understood by reading the subsequent detailed description and examples with references made to the accompanying drawings, wherein:

FIG. 1 is a cross section of an embodiment of a liquid crystal display (LCD) device according to the present invention;

FIG. 2 is a cross section of another embodiment of an LCD device according to the present invention;

FIG. 3 is a plan view of an embodiment of a color filter (CF) for an LCD device shown in FIGS. 1 and 2;

FIG. 4 is a plan view of another embodiment of a CF for an LCD device shown in FIGS. 1 and 2; and

FIG. 5 is a plan view of another embodiment of a CF for an LCD device shown in FIGS. 1 and 2.

### DETAILED DESCRIPTION OF INVENTION

The following description is of the best-contemplated mode of carrying out the present invention. This description is provided for the purpose of illustrating the general principles of the invention and should not be taken in a limiting sense. The scope of the invention is best determined by reference to the appended claims. Embodiments of a color filter (CF) for a liquid crystal display (LCD) device according to the invention are described with reference to the accompanying drawings.

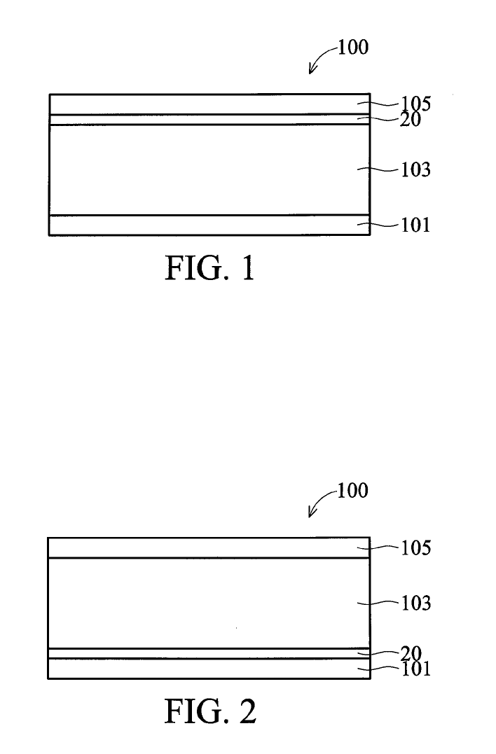

FIG. 1 illustrates a cross section of an embodiment of an LCD device 100. The LCD device 100 comprises a lower substrate 101, an upper substrate 105 opposite to the lower substrate 101, a liquid crystal layer 103, and a color filter 20. The lower substrate 101, such as a glass substrate or other transparent substrates, serves as an array substrate comprising a plurality of data lines and a plurality of scan lines perpendicularly interlaced to form a plurality of pixel regions. In order to simplify the diagram, only a flat substrate 101 is depicted. The upper substrate 105, such as a glass substrate or other transparent substrates, serves as a CF substrate having a CF 20 thereon. The liquid crystal layer 103 is disposed between the upper substrate 105 and the lower substrate 101. In the embodiment, the CF 20 is disposed between the liquid crystal layer 103 and the upper substrate 105. In another embodiment, as shown in FIG. 2, the CF 20 may be disposed on the lower substrate 101, such that the CF 20 is between the liquid crystal layer 103 and the lower substrate 101. The lower substrate 101, such as a glass substrate or other transparent substrates, serves as an array substrate comprising a plurality of data lines and a plurality of scan lines perpendicularly interlaced to form a plurality of pixel regions. In order to simplify the diagram, only a flat substrate 101 is depicted.

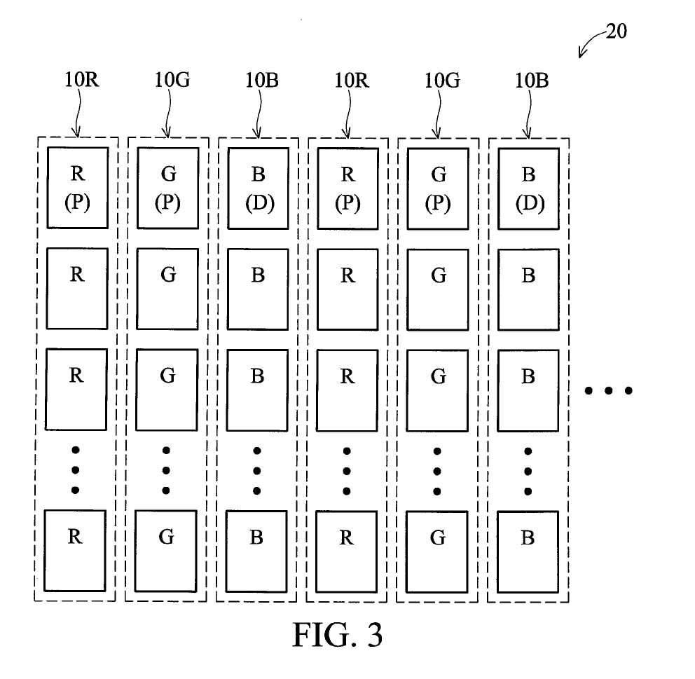

Referring to FIG. 3, which is a plan view of an embodiment of a CF for an LCD device shown in FIGS. 1 and 2. The CF 20 comprises a plurality of series of red resist pattern layers 10R constituted of red resist pattern layers R, a plurality of series of green resist pattern layers 10G constituted of green resist pattern layers G, and a plurality of series of blue resist pattern layers 10B constituted of blue resist pattern layers B. The plurality of series of red resist pattern layers 10R, the plurality of series of green resist pattern layers 10G, and the plurality of series of blue resist pattern layers 10B are alternately arranged in an array. In this embodiment, each of the plurality of series of red resist pattern layers 10R and each of the plurality of series of green resist pattern layers 10G comprise a colorant consisting of pigment P, respectively. For example, the pigment P used for the series of red resist pattern layers 10R may comprise PR254, PR177, PR209, or PY139. Moreover, the pigment P used for the series of green resist pattern layers 10G may comprise PG36 or PY150.

Unlike the series of red resist pattern layers 10R and the series of green resist pattern layers 10G, each of the plurality of series of blue resist pattern layers 10B comprise a colorant consisting of dye D. For example, the dye D used for the series of blue resist pattern layers 10B may comprise triallylimethane dye. The particle size of dye D is very small, causing low light scattering to mitigate dark-state light leakage of LCD device. Moreover, the inventor discovered that the blue light may produce higher interference than red or green light due to the property of the liquid crystal layer, resulting in a bluish color at the dark-state of the LCD device. Accordingly, the plurality of series of blue resist pattern layers 10B with a colorant consisting of dye D is capable of mitigating dark-state light leakage of LCD device, while alleviating bluish color at the dark-state of the LCD device.

In another embodiment, at least one of the plurality of series of blue resist pattern layers 10B comprises a colorant consisting of dye D, and the others comprise a colorant consisting of pigment P. For example, the pigment P used for the series of blue resist pattern layers 10B may comprise PB15:6 or PV23. In yet another embodiment, some of the blue resist pattern layers B in each of the plurality of series of blue resist pattern layers 10B comprise a colorant consisting of dye D, and the others in each of the plurality of series of blue resist pattern layers 10B comprise a colorant consisting of pigment P.

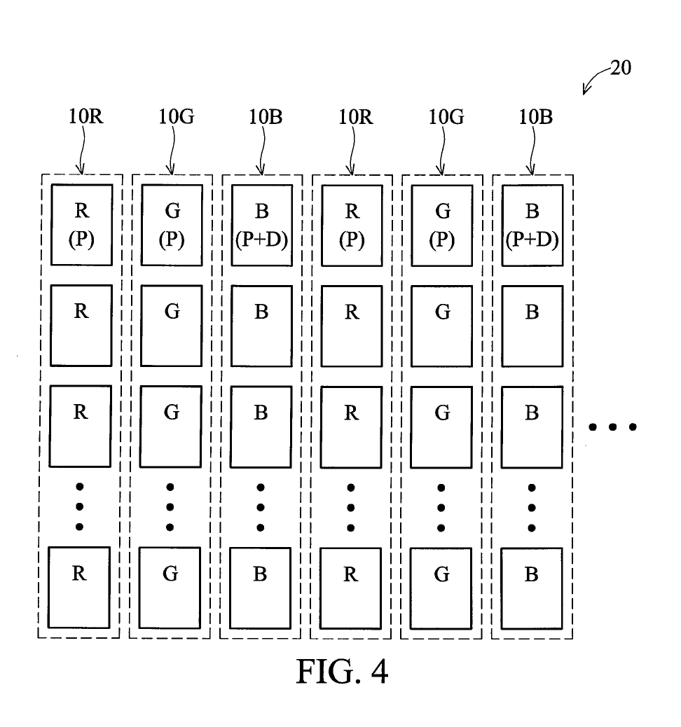

Referring to FIG. 4, which is a plan view of another embodiment of a CF for an LCD device shown in FIGS. 1 and 2. Elements in FIG. 4 that are the same as in FIG. 3 are labeled the same and are not described again for brevity. In this embodiment, each of the plurality of series of red resist pattern layers 10R and each of the plurality of series of green resist pattern layers 10G comprise a colorant consisting of pigment P, respectively. Unlike the series of red resist pattern layers 10R and the series of green resist pattern layers 10G, each of the plurality of series of blue resist pattern layers 10B comprise a colorant consisting of a mixture of dye D and pigment P. For example, the dye D in the mixture used for the series of blue resist pattern layers 10B may comprise triallylimethane dye and the pigment P in the mixture may comprise PB15:6 and PV23. Moreover, the ratio of solid content between the dye D and pigment P is about 3:7.

In another embodiment, at least one of the plurality of series of blue resist pattern layers 10B comprises a colorant consisting of a mixture of dye D and pigment P, and the others comprise a colorant consisting of pigment P. In yet another embodiment, some of the blue resist pattern layers B in each of the plurality of series of blue resist pattern layers 10B comprise a colorant consisting of a mixture of dye D and pigment P, and the others in each of the plurality of series of blue resist pattern layers 10B comprise a colorant consisting of pigment P.

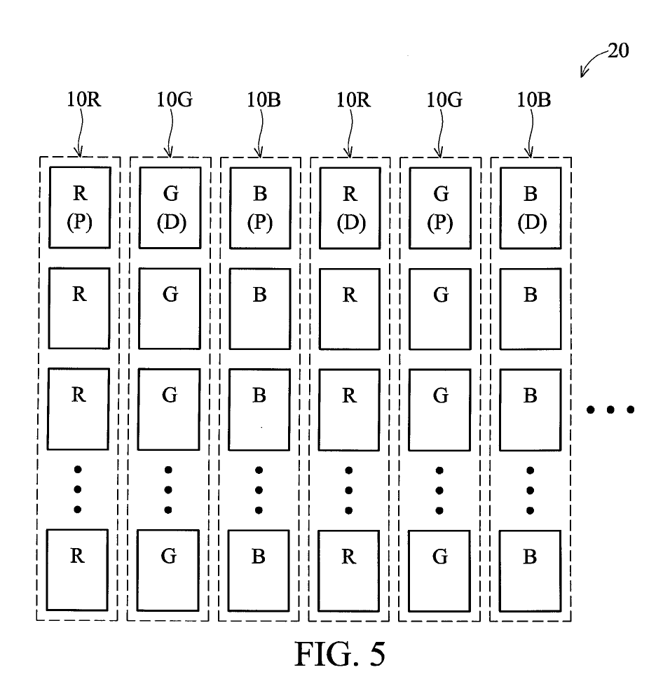

Referring to FIG. 5, which is a plan view of further another embodiment of a CF for an LCD device shown in FIGS. 1 and 2. Elements in FIG. 5 that are the same as in FIG. 3 are labeled the same and are not described again for brevity. In this embodiment, the array alternately arranged by the pluralities of series of red, green, and blue resist pattern layers 10R, 10G, and 10B, and the plurality of odd series of red, green, and blue resist pattern layers 10R, 10G, and 10B, comprise colorants consisting of pigment P and the plurality of even series of red, green, and blue resist pattern layers 10R, 10G, and 10B comprise colorants consisting of dye D. That is, the two adjacent series of resist pattern layers comprise different types of colorant (i.e. pigment P and dye D). Typically, the light transmission of the dye D is higher than that of the pigment P.

In the embodiment, the pigment P used for the plurality of odd series of red resist pattern layers 10R may comprise PR254, PR177, PR209, or PY139, and the dye D used for the plurality of even series of red resist pattern layers 10R may comprise xanthene dye or pirazolone azo dye. Moreover, the pigment P used for the plurality of odd series of green resist pattern layers 10G may comprise PG36 or PY150, and the dye D used for the plurality of even series of green resist pattern layers 10G may comprise copper phthalocyanine dye or pyridone azo dye. Additionally, the pigment P used for the plurality of odd series of blue resist pattern layers 10B may comprise PB15:6 or PY23, and the dye D used for the plurality of even series of blue resist pattern layers 10B may comprise triallylimethane dye.

According to the embodiments of the invention, since some of the series of resist pattern layers comprise colorants consisting of dye having a particle size smaller than that of pigment, thus producing lower light scattering than that of the pigment, dark-state light leakage of LCD device can be mitigated. Moreover, since some of or each of the plurality of series of blue resist pattern layers 10B uses the dye as a colorant, bluish coloring at the dark-state of the LCD device can be alleviated.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A color filter, comprising:
a plurality of series of red resist pattern layers, a plurality of series of green resist pattern layers, and a plurality of series of blue resist pattern layers alternately arranged in an array;
wherein each of the plurality of series of red resist pattern layers and each of the plurality of series of green resist pattern layers comprise a colorant consisting of pigment, respectively, and at least one series of blue resist pattern layers comprise a colorant consisting of dye or a mixture of dye and pigment.

2. The color filter of claim 1, wherein each of the plurality of series of blue resist pattern layers comprise the colorant consisting of the mixture of dye and pigment and the ratio of solid content between the dye and pigment is about 3:7.

3. The color filter of claim 1, wherein the pigment for each of the plurality of series of red resist pattern layers comprises PR254, PR177, PR209, or PY139.

4. The color filter of claim 1, wherein the pigment for each of the plurality of series of green resist pattern layers comprises PG36 or PY150.

5. The color filter of claim 1, wherein each of the plurality of series of blue resist pattern layers comprise the colorant consisting of dye comprising triallylimethane dye.

6. The color filter of claim 1, wherein each of the plurality of series of blue resist pattern layers comprise the colorant consisting of a mixture of dye and pigment, and the dye in the mixture comprises triallylimethane and the pigment in the mixture comprises PB15:6 or PV23.

7. A color filter, comprising:
a plurality of series of red resist pattern layers, a plurality of series of green resist pattern layers, and a plurality of series of blue resist pattern layers alternately arranged in an array;
wherein the plurality of odd series of red, green, and blue resist pattern layers in the array comprises colorants consisting of pigment and the plurality of even series of red, green, and blue resist pattern layers in the array comprises colorants consisting of dye.

8. The color filter of claim 7, wherein the pigment for the series of red resist pattern layers comprises PR254, PR177, PR209, or PY139 and the dye for the series of red resist pattern layers comprises xanthene dye or pirazolone azo dye.

9. The color filter of claim 7, wherein the pigment for the series of green resist pattern layers comprises PG36 or PY150 and the dye for the series of green resist pattern layers comprises copper phthalocyanine dye or pyridone azo dye.

10. The color filter of claim 7, wherein the pigment for the series of blue resist pattern layers comprises PB15:6 or PV23 and the dye for the series of blue resist pattern layers comprises triallylimethane dye.

11. A liquid crystal display device, comprising:
a lower substrate and an upper substrate opposite thereto;
a liquid crystal layer disposed between the lower and upper substrates; and
a color filter, disposed between the liquid crystal layer and the upper substrate, comprising:
a plurality of series of red resist pattern layers, a plurality of series of green resist pattern layers, and a plurality of series of blue resist pattern layers alternately arranged in an array;
wherein each of the plurality of series of red resist pattern layers and each of the plurality of series of green resist pattern layers comprise a colorant consisting of pigment, respectively, and at least one series of blue resist pattern layers comprise a colorant consisting of dye or a mixture of dye and pigment.

12. The liquid crystal display device of claim 11, wherein each of the plurality of series of blue resist pattern layers comprise the colorant consisting of the mixture of dye and pigment and the ratio of solid content between the dye and pigment is about 3:7.

13. The liquid crystal display device of claim 11, wherein the pigment for each of the plurality of series of red resist pattern layers comprises PR254, PR177, PR209, or PY139.

14. The liquid crystal display device of claim 11, wherein the pigment for each of the plurality of series of green resist pattern layers comprises PG36 or PY150.

15. The liquid crystal display device of claim 11, wherein each of the plurality of series of blue resist pattern layers comprise the colorant consisting of dye comprising triallylimethane dye.

16. The liquid crystal display device of claim 11, wherein each of the plurality of series of blue resist pattern layers comprise the colorant consisting of a mixture of dye and pigment, and the dye in the mixture comprises triallylimethane and the pigment in the mixture comprises PB15:6 or PV23.

17. A liquid crystal display device, comprising:
a lower substrate and an upper substrate opposite thereto;
a liquid crystal layer disposed between the lower and upper substrates; and
a color filter, disposed between the liquid crystal layer and the upper substrate, comprising:
a plurality of series of red resist pattern layers, a plurality of series of green resist pattern layers, and a plurality of series of blue resist pattern layers alternately arranged in an array;
wherein the plurality of odd series of red, green, and blue resist pattern layers in the array comprise colorants consisting of pigment and the plurality of even series of red, green, and blue resist pattern layers in the array comprises colorants consisting of dye.

18. The liquid crystal display device of claim 17, wherein the pigment for the series of red resist pattern layers comprises PR254, PR177, PR209, or PY139 and the dye for the series of red resist pattern layers comprises xanthene dye or pirazolone azo dye.

19. The liquid crystal display device of claim 17, wherein the pigment for the series of green resist pattern layers comprises PG36 or PY150 and the dye for the series of green resist pattern layers comprises copper phthalocyanine dye or pyridone azo dye.

20. The liquid crystal display device of claim 17, wherein the pigment for the series of blue resist pattern layers comprises PB15:6 or PV23 and the dye for the series of blue resist pattern layers comprises triallylimethane dye.
